(19) United States
(12) Patent Application Publication
(10) Pub. No.: US 2006/0126853 A1
(43) Pub. Date: Jun. 15, 2006

(54) Audio signal processing method and apparatus

(75) Inventor: Shinji Kobayashi, Chiba (JP)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Sony Corporation, Tokyo (JP)

(21) Appl. No.: 11/300,200

(22) Filed: Dec. 14, 2005

(30) Foreign Application Priority Data
Dec. 15, 2004 (JP) 2004-363571

(51) Int. Cl. H04R 5/00; H03G 3/00

(52) U.S. Cl. 381/17; 381/104; 381/309

(57) ABSTRACT

In case of carrying out a correction process for outputting an inputted audio signal from a speaker having a predetermined input-output characteristic and in a case, as for the predetermined input-output characteristic of the speaker, when characteristic in which linearity of an output level with respect to an input signal is approximately assured in a level equal to a predetermined level or more and the output level with respect to the input signal becomes high at the level equal to the predetermined level or less is selected, a correction process for lowering an amount of the output level which becomes high with respect to a signal component approximately of the level equal to the predetermined level or less in an inputted audio signal is carry out. Owing to the correction process, reproduction characteristic is improved on an occasion of a small volume in a small sized speaker such as a headphone.

### CROSS-REFERENCES TO RELATED APPLICATIONS

The present invention contains subject manner related to Japanese Patent Application JP 2004-363571 filed in the Japanese Patent Office on Dec. 15, 2004, the entire contents of which being incorporated herein by reference.

### BACKGROUND OF THE INVENTION

The present invention relates to an audio signal processing method and apparatus which carry out characteristic correction in case of reproducing an audio signal from a speaker and more particularly relates to a technology preferably to be applied in case of reproducing a speaker for a headphone.

In the past, various kinds of types were in practical use as a speaker for a headphone by which reproduction of a high-quality sound is possible. A speaker unit for a headphone is to be set on a head portion of a listener, so that there is a restriction in size and a speaker unit having a relatively small size of around several 10 mm in diameter is used.

In a case when an audio signal is reproduced by using such a headphone, a case occurred in which there was a problem in the reproduction characteristic of a small signal owing to a fact that a vibration system such as a diaphragm or the like has a very lightweight, because the speaker unit has a small size. As one of the processes for solving the problem of such as a reproduction characteristic, there is a case in which characteristic correction of an audio signal is carried out on the side of equipment which supplies the audio signal to the headphone. As one of characteristic corrections known in the past, there is a case in which, for example, a correction referred to as a loudness control is carried out. This loudness control is a control for carrying out a correction process which strengthens a bass portion and a treble portion in the output level thereof as compared with a midrange portion such that a phenomenon that the bass and treble portions sound insufficiently mainly on an occasion of a small volume is to be corrected.

In a patent reference 1, there is a description with respect to one example of a reproducing constitution in case of carrying out a loudness correction.

[Patent Reference 1] Jap. Laid-Open Publication 2002-171589

However, the loudness control is a correction process of reproduction characteristic assuming that an output from a so-called stationary type speaker device is introduced and in case of reproducing from a headphone, there is a case in which the reproduction balance is upset conversely by a correction process for strengthening the bass portion and the treble portion in the output level as compared with the midrange portion.

More specifically, a speaker unit for a headphone generally has a small size and a lightweight, so that a vibration system such as a diaphragm or the like is very lightweight and in a case when input-output characteristic with respect to a sound having a level more than a certain degree is set approximately linearly, the output sensitivity with respect to the input becomes too high for a certain level or less and as a result there are many situations in which linearity of the output with respect to the input is to be deteriorated.

Specifically, a sound which should sound primarily small would sound large and it may happen that listening of long hours will be fatigable. As being seen from the reproduction characteristic, there is obtained a reproduced sound in which consonants and harmonics are emphasized more than it is necessary. A phenomenon in which a clicking sound leaks in the surrounding area of the headphone is related mainly to such a signal component.

Here, a concrete characteristic example with respect to a signal having a relatively small level is shown in FIGS. 1 AND 2, wherein in a case, for example, when a signal waveform S1 shown in FIG. 1A or a signal waveform S3 shown in FIG. 1B is inputted to a speaker unit in a headphone, the sound waveform actually outputted from the headphone comes to have a level in a high state caused by a phenomenon such that the vibration of the vibration system overshoots or the like as shown by a waveform 2 or a waveform 4.

FIGS. 2A and 2B are drawings inspecting such a state by output characteristics of the headphone at every frequency and drawings showing output characteristics from a low band to a high band in signal levels of a plurality of steps, wherein FIG. 2A shows an ideal characteristic and FIG. 2B is a drawing showing an output characteristic of an actual headphone. As shown in FIG. 2A, it is assumed in an ideal state such that four levels L1, L2, L3 and L4 were spaced approximately equally and it was a flat characteristic from a low band to a high band. At that time, with respect to the levels L1, L2 and L3 having high output levels for the output characteristic of an actual headphone shown in FIG. 2B, output characteristics approximately comparable with the ideal characteristic can be assured, but with respect to the characteristic of the lowest level L4, the levels are to be heightened from the primarily necessary levels by sensitivity a in any frequency bands.

The input-output characteristic diagram of FIG. 3 is a drawing when such sensitivity lowering is seen as a specific frequency characteristic. As shown in FIG. 3, while it is necessary primarily that the output level increased linearly with respect to the increase of the input signal level to the headphone so as to obtain a characteristic x of a dotted line, actually, the level changes approximately linearly in a level of a certain degree or more, but motion of the diaphragm with respect to the input is bad in a specific level or less such that a curved characteristic y is obtained in which the output sensitivity with respect to the input is too high.

It should be noted that the characteristics explained so far were explained by taking a speaker unit for a headphone as an example, there also exists a constitution of a speaker unit other than a speaker unit for a headphone in a case when it is a speaker unit having a relatively small size in which linearity of the input-output characteristic of a small level signal cannot be maintained similarly.

### SUMMARY OF THE INVENTION

The present invention was invented in view of above aspects and is directed to improving reproduction characteristic of a small level signal.

According to the present invention, it is constituted in case of carrying out a correction process for outputting an inputted audio signal from a speaker having a predetermined input-output characteristic and in a case, as for the predetermined input-output characteristic of the speaker, when characteristic in which linearity of an output level with respect to an input signal is approximately assured in a level equal to a predetermined level or more and the output level with respect to the input signal becomes high at the level equal to the predetermined level or less is selected such that a correction process for lowering an amount of the output level which becomes high with respect to a signal component approximately of the level equal to the predetermined level or less in an inputted audio signal is carry out.

By doing like this, an audio signal is obtained as an audio signal outputted from a speaker in which the input-output characteristic thereof corrected in conformity with the characteristic of the speaker device is approximately linear and particularly, a signal of relatively small level whose output level becomes high under a normal condition is to be outputted favorably by the primary level.

According to the present invention, an audio signal is obtained as an audio signal outputted from a speaker device in which the input-output characteristic corrected in conformity with the characteristic of the speaker device is approximately linear and particularly, a signal of relatively small level whose output level becomes high under a normal condition is to be outputted favorably by the primary level, so that it is possible to improve the reproduced sound quality of a relatively small sized speaker remarkably.

Also, it is constituted such that a correction process of the output level is carried out approximately uniformly within the approximately all frequency bands which the speaker device outputs, so that the reproduction characteristic can be improved in all the frequency bands it becomes possible to carry out a high-fidelity reproduction with respect to the input audio signal, which is quite different from the strengthening of only a specific band carried out from the past such as a loudness control.

Also, by making it in conformity with the characteristic of a speaker for a headphone, it is possible to improve reproduction characteristic of a headphone or an earphone effectively.

### BRIEF DESCRIPTION OF THE DRAWINGS

FIGS. 1A and 1B are explanatory diagrams showing an example of output waveforms of a speaker of related art;

FIG. 2A is an explanatory diagram showing an example of output characteristic of an ideal speaker;

FIG. 2B is an explanatory diagram showing an example of output characteristic of a speaker of related art;

FIG. 3 is an explanatory diagram showing an example of input-output characteristic of a speaker of related art;

FIG. 4 is a block diagram showing a system constitutional example according to one exemplified embodiment of the present invention;

FIG. 5 is a block diagram showing a constitutional example according to one exemplified embodiment of the present invention;

FIG. 6 is a characteristic diagram showing an example of compensation characteristic according to one exemplified embodiment of the present invention; and

FIGS. 7A to 7C are characteristic diagrams showing an example of a correction state according to one exemplified embodiment of the present invention in which output sensitivity at every frequency is shown.

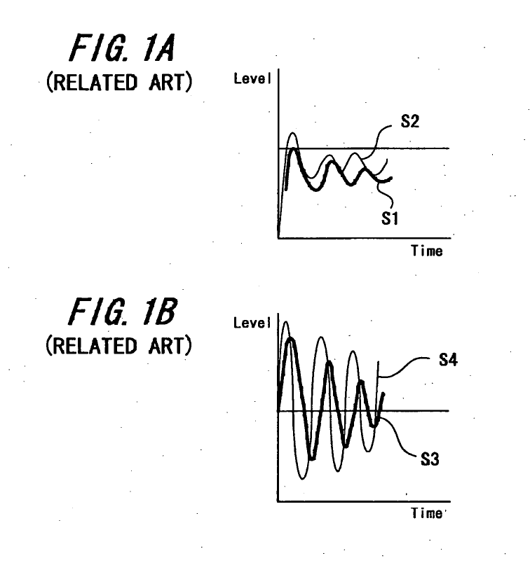

### DETAILED DESCRIPTION

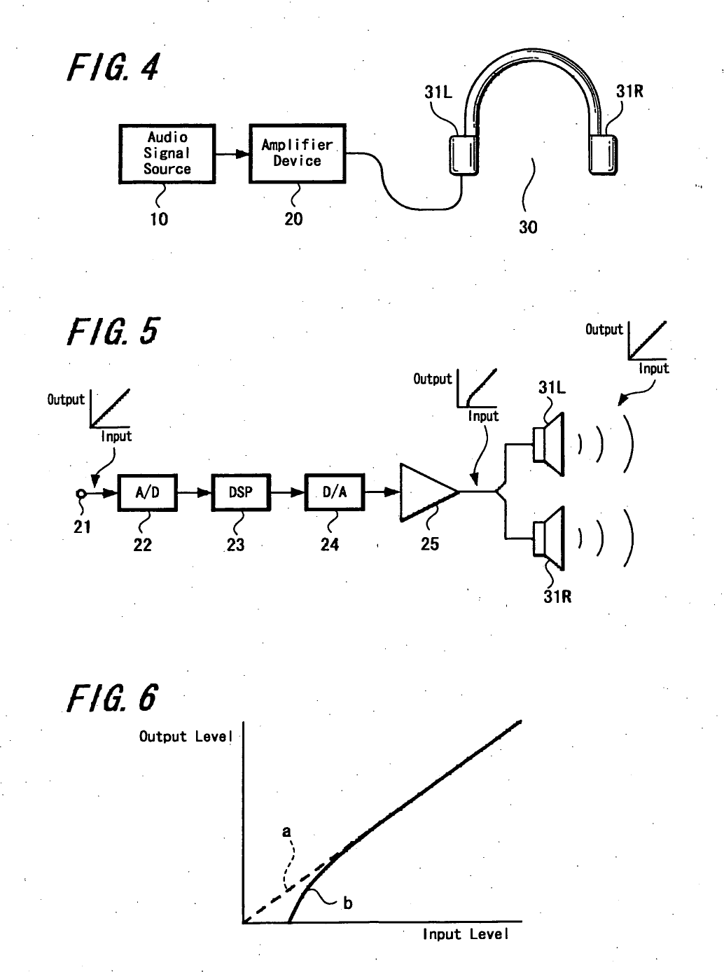

Hereinafter, a one exemplified embodiment of the present invention will be explained with reference to FIGS. 4 to 7. FIG. 4 a drawing showing a system constitutional example according to this exemplified embodiment. In this example, there is shown an audio reproduction system connected with a headphone and FIG. 4 is a drawing showing the whole system constitutional example. In this example, an audio signal source 10 is connected to an amplifier device 20, an audio signal recorded (stored) in a medium of a CD (disc), memory or the like is reproduced by the audio signal source 10, the reproduced and outputted audio signal is supplied to the amplifier device 20 and a process is carried out in the amplifier device 20 for making an audio signal which is supplied to the headphone. It may be constituted such that the audio signal source 10 and the amplifier device 20 are integrated each other.

In case of this example, the audio signal audio outputted from the signal source 10 is a signal of two channels consisting of an audio signal for the left channel and an audio signal for the right channel. The audio signal outputted from the amplifier device 20 is supplied to a headphone 30. The headphone 30 is provided with a speaker unit 31L for the left channel and a speaker unit 31R for the right channel and the audio signal of the corresponding channel is supplied to each the channel unit from the amplifier device 20.

It will be explained with respect to the speaker units 31L and 31R which the headphone 30 of this example is provided with, wherein each of the speaker units 31L and 31R is a so-called full-range type speaker unit having approximately flat frequency characteristic in audible bands as characteristic seen from the outputted frequency bands and having characteristic in which it is outputted from a low band to a high band and it is constituted such that they are provided with relatively small sized diaphragms and have shapes being mounted on the headphone 30 respectively. With respect to the speaker unit 31L or 31R, the vibration system such as the diaphragm or the like has a relatively small size, so that there is used such a unit in which linearity of input-output characteristic for a large signal equal to a predetermined level or more is approximately maintained, linearity of the input-output characteristic is not assured for the level equal to the predetermined level or less and the output signal level becomes high with respect to the input signal level. More specifically, a speaker unit having the characteristic y which is explained in the column of “Background Art” with reference to FIG. 3 is to be used. A speaker unit possessing such a characteristic is a general unit as a speaker unit for a headphone.

According to this example, it is constituted in an audio reproduction system in which a headphone 30 using the speaker units 31L and 31R possessing such a characteristic is connected such that a signal characteristic correction is carried out on the side of the amplifier device 20 which processes an audio signal to be supplied to the headphone 30.

FIG. 5 a drawing showing a constitution for a characteristic correction within the amplifier device 20 of this example and it shows a connection constitution until the speaker units 31L and 31R in the headphone 30. As shown in FIG. 5, an audio signal obtained at an audio signal input terminal 21 of the amplifier device is supplied to an analog/digital converter 22 so as to be converted to a digital audio signal and the converted digital audio signal is supplied to a DSP (digital-signal-processor) 23. Then, a correction process of the audio signal characteristic is carried out by a digital operation process in the DSP 23. More specifically, for example, a signal component equal to a predetermined level or more and a signal component of less than the predetermined level are separated by the digital operation process with respect to all frequency bands and nothing of correction process is carried out with respect to the signal component equal to the predetermined level or more. Then, with respect to the signal component of less than the predetermined level, a correction such as suppressing the output level with respect to the input level is carried out. Specifically, a correction process is carried out by the digital operation so as to become a characteristic such as shown by a curve b (FIG. 6) in which the linearity is not given such that the lower the level is the higher the rate of decrease becomes as compared with a characteristic a. It will be described later with respect to the detail of the correction process.

Then, the signal component equal to the predetermined level or more without the correction process and the signal component less than the predetermined level for which the correction process was carried out are composed in the DSP 23 and the composed signal is supplied to a digital/analog converter 43 to be converted to an analog audio signal.

The converted analog audio signal is supplied to an amplifier 25 so as to be amplified for the headphone drive and the amplified audio signal is supplied to the speaker unit 31L and 31R in the headphone 30 so as to output an audio signal (sound emission).

Next, it will be explained with respect to a correction processing state in the DSP 23 of this example. In this example, for example, a correction such as shown by a characteristic b shown in FIG. 6 is carried out. In FIG. 6, a characteristic a shown by a dotted line is a characteristic in which linearity is given such that increase and decrease of the input level and increase and decrease of the output level are linearly proportional to each other and it is shown just for reference. A characteristic b shown by a solid line is a characteristic corrected the DSP 23 according to this example.

As shown as the characteristic b, it is constituted such that linearity is given in a region equal to a predetermined level or more (region shown by the straight line in characteristic b) wherein the increase and decrease of the input level and the increase and decrease of the output level are linearly proportional (that is, characteristic approximately coincide with the characteristic a) and in the region equal to the predetermined level or less, the output level with respect to the input level has a characteristic shown by a curve which lowers the level wherein the lower the level is the higher the rate of increase becomes as compared with a characteristic a.

Here, it is constituted with respect to a level position at which the straight line and the curve change in the characteristic b such that it approximately coincides with a level at the changing point between a level region in which linearity of the input-output characteristic is approximately maintained and a level region in which linearity of the input-output characteristic is not assured with respect to the characteristic of the connected speaker units 31L and 31R of the headphone 30 (that is, predetermined level mentioned above). Also, with respect to the characteristic which determines the curved shape of the characteristic b, it is set to a characteristic in which the input and the output of the input-output characteristic of the speaker unit such as shown in FIG. 3 are reversed. Such a characteristic setting is executed, for example, by the condition or the like of the correction operation in case of operation-processing in the DSP 23.

It should be noted that the characteristic b shown in FIG. 6 shows a characteristic in a specific frequency and in case of this example, it is constituted such that the speaker units 31L and 31R possess approximately similar characteristic in all of reproducible and audible bands.

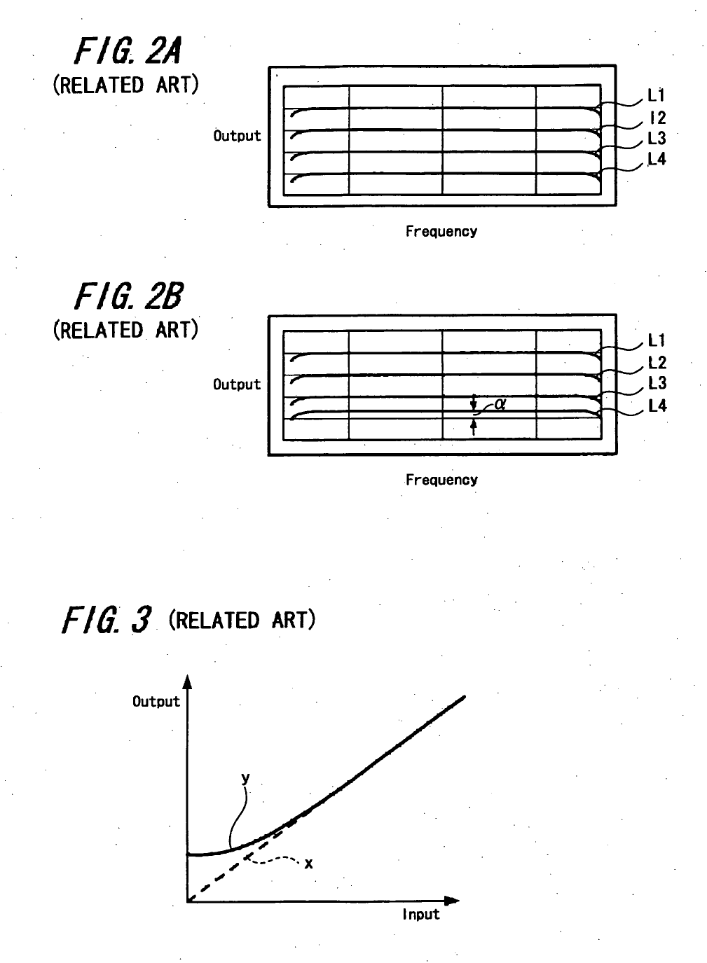

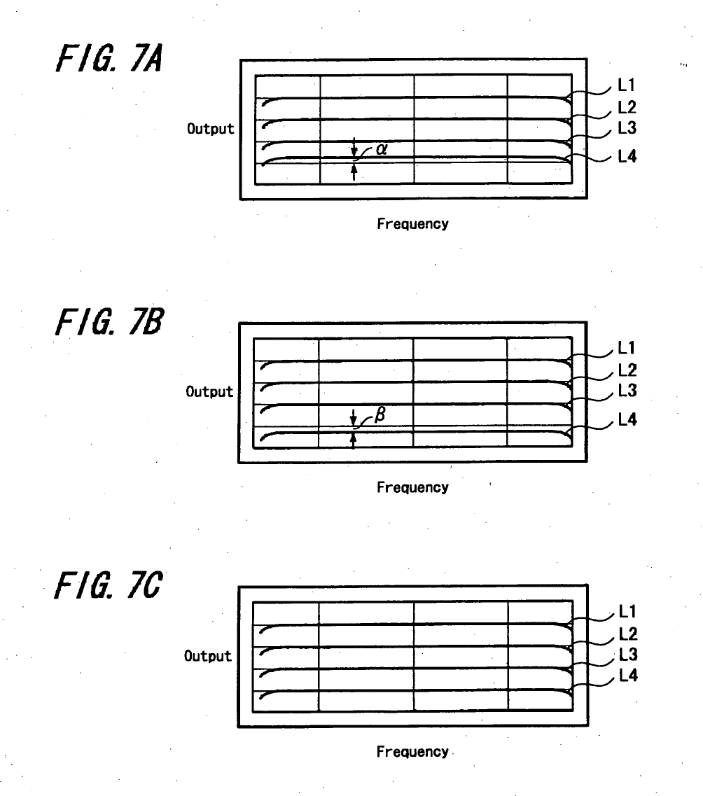

FIG. 7 is a drawing showing a state in which the audio signal is outputted from the headphone 30 by such a correction as an output characteristic from a low band to a high band in a plurality of steps of the signal level. FIG. 7A is a drawing showing an output characteristic which the headphone 30 itself of this example possesses (that is, output characteristic without being corrected). This FIG. 7A is same as the speaker characteristic shown in FIG. 2B as “Background Art”. More specifically, as shown in FIG. 7A, with respect to levels L1, L2 and L3 whose output levels are high, output characteristics approximately comparable with the ideal characteristic can be assured, but with respect to the output characteristic of the lowest level L4, the levels are to be heightened from the primarily necessary levels by sensitivity α in any frequency bands.

Here, a correction which becomes characteristic b shown in FIG. 6 in all frequency bands is carried out according to the correction in the amplifier device 20, so that when considered about the output characteristic of the signal inputted to the amplifier device 20, as shown in FIG. 7B, with respect to the levels L1, L2 and L3 having high output levels, they do not change from the input level, but with respect to the output characteristic of the lowest level L4, the levels are to be raised from the primary levels by sensitivity β in any frequency bands. Here, the sensitivity β which becomes low is to be set to a level for approximately correcting the sensitivity a of FIG. 7A which becomes high in the speaker device 30.

After making it as such a characteristic, the audio signal processed in the amplifier device 20 is outputted from the headphone 30, so that with respect to the characteristic of the audio outputted from the headphone 30, as shown in FIG. 7C, it becomes a characteristic in which the four levels L1, L2, L3 and L4 are spaced approximately equally and they are flat from a low band to a high band and becomes a favorable characteristic which is approximately equal to the ideal characteristic shown in FIG. 2A, in which the input and the output coincide with each other regardless of the amplitude thereof in all frequency bands.

Consequently, according to the audio reproduction system of the present invention, it is possible to output the reproduced audio signal of the audio signal source 10 from the headphone 30 by a high-quality sound. Such a reproduction characteristic is a characteristic which is quite different from a process such as a loudness control known in the past in which the signal is strengthened with respect to the signal in a specific frequency band regardless of the level thereof and is a characteristic which carries out a reproduction faithful to the input audio signal.

It should be noted in the above-mentioned exemplified embodiment that it was constituted such that a correction process is carried out by a digital operation using the DSP, but it may be constituted such that a circuit carrying out a similar correction by an analog circuit is to be mounted.

Also, it was constituted in the above-mentioned exemplified embodiment such that an audio signal correction is carried out within the audio amplifier device, but it may be constituted such that a circuit for carrying out a similar correction is provided on the side of the audio signal source. Alternatively, it may also be constituted such a circuit for carrying out a similar correction is to be provided within the headphone.

Alternatively, it may also be constituted such that a program for realizing a function carrying out a similar audio signal correction as the above-mentioned exemplified embodiment is mounted on an arithmetic processing apparatus such as a personal computer apparatus and a characteristic correction process of the audio data stored in the apparatus is to be carried out by the arithmetic process according to the program.

Also, in each of the exemplified embodiments mentioned above, it was explained with respect to a case in which reproduction is carried out by a headphone provided with two speaker units of right and left, but it is also applicable to a case in which reproduction is carried out by a speaker device using a small sized speaker unit which has an approximately similar characteristic as the speaker unit for the headphone mentioned above. For example, it may be constituted in an audio reproduction system installed within a vehicle such as a car or the like such that a similar correction process is to be carry out in case of reproducing by a small sized speaker device mounted on (built-in) a head resting portion of a seat thereof.

It should be understood by those skilled In the art that various modifications, combinations, sub-combinations and alterations may occur depending on design requirements and other factors insofar as they are within the scope of the appended claims or the equivalents thereof.

1. An audio signal processing method which carries out a correction process for outputting an inputted audio signal from a speaker having a predetermined input-output characteristic in a case, as for the predetermined input-output characteristic of said speaker, when characteristic in which linearity of an output level with respect to an input signal is approximately assured in a level equal to a predetermined level or more and the output level with respect to the input signal becomes high at the level equal to said predetermined level or less is selected, wherein a correction process for lowering an amount of said output level which becomes high with respect to a signal component approximately of the level equal to said predetermined level or less in an inputted audio signal is carry out.

2. An audio signal processing apparatus which carries out a correction process for outputting an inputted audio signal from a speaker having a predetermined input-output characteristic in a case, as for the predetermined input-output characteristic of said speaker, when characteristic in which linearity of an output level with respect to an input signal is approximately assured in a level equal to a predetermined level or more and the output level with respect to the input signal becomes high at the level equal to said predetermined level or less is selected, comprising:
correction means for carrying out a correction process for lowering an amount of said output level which becomes high with respect to a signal component approximately of the level equal to said predetermined level or less in an inputted audio signal.

3. An audio signal processing apparatus according to claim 2, wherein said correction means carries out a correction process of the output level approximately uniformly within approximately all frequency bands which said speaker outputs.

4. An audio signal processing apparatus according to claim 2, wherein the speaker having said characteristic is a speaker for a headphone.
